(19) United States
(12) Patent Application Publication
(10) Pub. No.: US 2011/0023938 A1
(43) Pub. Date: Feb. 3, 2011

(54) SOLAR POWER PLANT

(76) Inventors: Arthur R. Buchel, Ruggell (LI); Franz Baumgartner, Konstanz (DE)

Correspondence Address: MORRISS OBRYANT COMPAGNI, P.C., 734 EAST 200 SOUTH, SALT LAKE CITY, UT, 84102, US

(21) Appl. No.: 12/669,013

(22) PCT Filed: Jul. 14, 2008
(86) PCT No.: PCT/CH08/00315

§ 371 Date: Jun. 24, 2010

(30) Foreign Application Priority Data
Jul. 13, 2007 (CH) 1131/07

(51) Int. Cl. H01L 31/052

(52) U.S. Cl. 136/246

(57) ABSTRACT

A solar array in the form of a photovoltaic installation comprises a plurality of interspaced solar modules. Also provided, at a distance from the solar modules (11), are movable reflector elements (19) which have reflectors for reflecting the solar radiation and which are oriented in such a way that collected solar radiation is at least partially projected onto the receiving surface of an adjacent solar module (11).

### CROSS-REFERENCE TO RELATED APPLICATIONS

This application claims priority to PCT/CH2008/000315 filed on Jul. 14, 2008, and to CH113107 filed on Jul. 13, 2007, the entirety of each of which is incorporated by this reference.

### BACKGROUND

1. Field of the Invention

The present invention relates to a solar array, in particular a photovoltaic installation, comprising a plurality of interspaced solar modules.

2. Background of the Invention

Three different variants are typically used for configuring conventional photovoltaic modules in solar power plants. According to a first variant, fixedly mounted solar modules with a southerly orientation are used (in the Northern Hemisphere; otherwise, a northerly orientation is used)

According to a second variant, module tracking systems are used, which by means of uniaxial rotation allow tracking of the normal vector of the module panel for optimized orientation to the direction of solar radiation.

According to a third variant, a tracking system allows tracking of the normal vector of the solar module in two different directions. This permits the orientation of the solar module to be changed in the east-west direction as well as in the north-south direction to allow optimal orientation to the particular solar altitude.

In the first variant, the module utilization is best when the individual modules are spaced apart at a multiple of the module positioning height (FIG. 1). These are the only conditions that prevent shadows from being cast on modules by a module situated farther to the front when the solar altitude is low in the morning and late afternoon. Even for solar arrays having tracked solar modules (see FIG. 2), a spacing of individual solar modules in the range of three times the module height is recommended. Solar arrays have a large space requirement due to the great distances between the modules. Furthermore, the energy yield per required unit surface area is low.

Arrays having biaxial tracking (third variant) result in optimal energy yield per module, provided that they are spaced at a sufficient distance apart to prevent shading. However, these arrays are mechanically complicated and costly, and also have a low energy yield per required unit surface area.

For flat solar radiation angles, shading may be reduced for trackable modules by positioning same at a small angle with respect to the horizontal. (FIG. 3). However, module utilization is not optimal in such a configuration, since the grazing solar radiation strikes the module surface only at a very flat angle. That is to say, the incident solar radiation could also be absorbed using a much smaller module surface if the module surface were optimally oriented. A further disadvantage is that for a flat angle of incidence the radiation is introduced less efficiently into the solar module.

Even if the solar modules are optimally oriented with respect to the sun, the maximum incident solar radiation is approximately 1000 W/m^{2,} although currently available solar modules are basically able to process even greater radiation capacities.

U.S. Pat. No. 4,282,394 discloses a lightweight solar cell array for space vehicles which allows bundling of the incident radiation on the solar module. The solar cell array comprises a plurality of articulatedly connected solar cell devices which may be folded up for transport and then unfolded for use in a planar configuration. Light is reflected onto the solar cells by a flexible reflector assembly provided below the solar cell array. The solar cell devices are articulatedly connected by means of hinges. This allows the solar cells to be folded up in an accordion-like manner and stowed in a housing. The reflectors are likewise composed of individual sections which are hinged together. In U.S. Pat. No. 4,282,394 the foldable solar cell arrays and the reflectors are used exclusively to allow reduction to the smallest possible volume for transport.

US 202 [sic; 2002]/0075579 describes a solar array comprising a plurality of concave reflector elements and a receiver. The array concentrates and converts radiant energy, such as sunlight, to other forms of energy such as electricity or heat. The concave reflector elements are positioned so that the energy portions reflected from the individual surfaces are focused and superimposed to form a common focal region on the receiver. The reflector elements and the receiver are provided on a frame in such a way that solar radiation striking the reflector elements at an angle is reflected onto the receiver situated at a distance from the reflector elements. US 2002/0075579 provides for positioning of the solar array on a biaxial support to allow optimal tracking of the position of the sun. However, a disadvantage of the solar array of US 2002/0075579 is that the curved reflector elements are relatively costly to manufacture. A further disadvantage is that tracking of the solar array according to the solar altitude requires a relatively complex mechanism.

A fundamentally different type of photovoltaic installation is the so-called concentrator system. In this system, the incident radiation is projected onto a small solar cell surface area by means of a reflector. However, at high light concentrations this system requires specialized solar cells with appropriate cooling and complex tracking of the reflectors as a function of the particular solar altitude.

Proceeding from this prior art, the present invention provides an improved solar array having improved energy yield per solar module. The present invention also provides a solar array in which the energy yield per required unit surface area is increased compared to conventional arrays.

### SUMMARY OF THE INVENTION

A solar array according to the invention provides reflector elements at a distance from the solar modules, that by means of a first tracking device the solar modules may be tracked about a first rotational axis, and by means of a second tracking device independent from the first tracking device the reflector elements may be tracked about a second rotational axis of the solar trajectory over the course of a day, so that solar radiation striking the reflector elements may be at least partially projected onto the receiver surface of an adjacent solar module. Compared to the conventional variants described at the outset, the present invention has the advantage that a higher annual energy yield per unit photovoltaic module surface area is achieved than for conventional fixed or tracked module systems. This results in reduced power generation costs. A further advantage is that a higher annual energy yield per m² of total array surface area is achieved, since in particular at steeper solar radiation angles (higher solar altitude) a greater proportion of the solar energy is projected onto the photovoltaic modules, and at that location is converted to electrical energy. Overall, this also results in improved cost efficiency for the array, since tracked reflector elements may be installed due to the low additional cost. The reflector elements also result in lower impingement of the ground area between the solar modules with solar radiation (shading). However, the shading caused by the reflector elements may also provide further advantages, depending on the utilization, for example for landscaping or shading of parking areas or roofs. At high wind speeds the configuration according to the invention has the advantage that the solar modules as well as the reflector elements may be oriented in such a way that the surface area on the array exposed to wind is minimal, resulting in high robustness and also allowing the mechanical design of the components to be optimized.

The reflectors may preferably be swiveled about at least one axis. This has the advantage that the reflectors may be oriented as a function of the solar altitude. The solar modules may also advantageously be pivotable about one axis, allowing swiveling of the solar modules and tracking of the solar trajectory. The energy yield may be maximized in this manner. In principle, the tracking devices may allow tracking about one or two axes. At least a third tracking device is also preferably provided to allow mutual swiveling of the solar modules and of the reflector elements about a further respective axis. This further axis is advantageously perpendicular to the respective swivel axes of the solar modules and reflector elements. In that case a third tracking device is sufficient when the solar modules and reflector elements are situated on a common supporting framework. However, in principle it is possible to provide separate (third and fourth) tracking devices about a further axis for swiveling of the solar modules and reflector elements.

It is advantageous to provide multiple rows of solar modules situated behind or adjacent to one another, and multiple rows of reflector elements. Each row of reflector elements is then located at a distance from the row of solar modules. Symmetrically configured rows of solar modules and reflector elements have the advantage that the space requirements are small, and tracking of the solar modules and reflector elements is possible with little complexity. It is practical for the reflector of the reflector element to allow bundling of the incident solar radiation. This has the advantage of increased efficiency of the solar array according to the invention.

The reflectors used may have a planar or a concave reflector surface. For large-area reflectors the concave reflector surface may be composed of a plurality of individual reflector surfaces having a planar surface. For the individual reflector surfaces, one or more adjusting devices may be provided for individual orientation of the individual reflector surfaces and optimal projection of the radiation onto an adjacent solar module. Each individual reflector surface may preferably be swiveled about at least one axis. This allows the energy yield to be maximized. Using a plurality of individual reflector surfaces having a planar surface has the advantage of lower cost.

The receiver surface of the solar modules is preferably oriented to the sun or solar trajectory, and the reflector modules are preferably oriented to at least one adjacent solar module. The solar elements and reflector elements may be connected to one another. In this case individual drives may be provided for the reflector elements as well as the solar modules. These drives may then be individually oriented using appropriate control software, for example.

To maximize the introduced radiation energy of the reflector onto the solar module, the largest possible dimensions of the reflector . elements are advantageous (FIG. 4; L_{R}; FIG. 5; L_{R}). This measure increases the density of the energy radiated onto the solar module, and thus the energy yield from the solar module. For large reflector widths, bundling of the incident radiation is preferably provided, for example by use of a concave mirror surface or a surface composed of multiple planar mirrors situated at an angle relative to one another in order to project the radiation, or composed of Fresnel elements. The reflector surface may be composed of multiple individual reflector surfaces which may preferably be individually oriented by means of separate adjusting devices (uniaxial or biaxial bearing), thereby maximizing the energy yield on the solar module. The reflector may also be composed of multiple independent reflector surfaces. It is also possible to use a flexible reflector element which allows the corresponding radiation projection.

It is also advantageous to orient the reflector element for a flat solar altitude in such a way that the entire solar radiation is directly absorbed by the solar modules, and no shading of the modules by the reflector elements occurs.

The rotational axes of the reflector elements and of the solar modules are advantageously parallel to one another. Depending on the design of the reflector elements, the projection of the radiation at right angles to the rotational axis of the solar modules may have an intensity profile of the incident radiation. It is therefore advantageous for the cells in the solar modules to be connected in parallel, at right angles to the rotational axis, to optimize the overall output.

The solar modules are advantageously composed of a plurality of interconnected solar cells. The solar cells are preferably designed for the highest possible current conduction (>60 mA/cm²) so that the electrical energy generated by the high level of incident solar radiation may also be conducted with minimal losses.

In contrast to the classical concentrator arrays, by use of the solar array according to the invention the conventional photovoltaic module technology may be used as an absorber, since the radiation density is only a small multiple of the solar radiation density without concentration, not a large multiple (>50) as is typical for concentrator arrays.

The present invention further relates to a method for generating power by use of a solar array wherein reflector elements are each situated at a distance from the solar modules, and may be swiveled about a rotational axis and tracked over the course of a day in such a way that incident sunlight is projected onto an adjacent solar module. This method has the advantage that the solar cells of the solar modules are better utilized, and more energy may be produced. In each case the solar modules and reflector elements are advantageously positioned one behind the other in alternation, preferably on a common supporting framework. Such a configuration conserves space, and allows a maximum energy yield per required unit surface area.

For a low solar altitude it is practical for the reflector elements to be oriented in such a way that shading of the adjacent solar module is avoided. The solar modules and reflector elements are each preferably tracked relative to the solar altitude about a further axis which is essentially perpendicular to the rotational axes of the reflector elements and solar modules. At high wind speeds the orientation of the reflector elements and/or the solar modules is preferably adjusted so that the resulting wind load is reduced: This has the advantage that the supporting structure for the solar array must have a smaller design. Accordingly, manufacture of the array according to the invention may be more favorable than for conventional arrays.

### BRIEF DESCRIPTION OF THE DRAWINGS

The invention is described in greater detail on the basis of an application example, with reference to the figures. The same reference numerals are used for identical parts in the figures, which show the following:

FIG. 1 schematically shows a known configuration of a solar array having fixed solar modules;

FIG. 2 schematically shows a known configuration of a solar array having solar modules which may be swiveled about an axis;

FIG. 3 schematically shows a known configuration of a solar array having solar modules which may be swiveled about an axis at flat solar radiation angles. An orientation angle β is selected such that for the particular angle of incidence a no shading is produced on the next module row;

FIG. 4 schematically shows a solar array according to the invention having solar modules which may be swiveled about an axis, and additional rotatable reflector elements for projection of the solar radiation at a steep angle of incidence;

FIG. 5 schematically shows a solar array according to the invention having solar modules which may be swiveled about an axis, and additional rotatable reflector elements for projection of the solar radiation at a flat angle of incidence;

FIG. 6 schematically shows the solar array of FIG. 4 with optimally oriented solar modules and reflector elements at low solar altitude;

FIG. 7a schematically shows a side view of a configuration of a solar array having solar modules which may be swiveled about an axis, and an additional rotatable reflector element, showing that the reflector element is designed to be longer at one or both ends of the module rows to allow projection of the sunlight onto the solar module, in the case that the solar radiation angle on the horizontal plane is not at right angles to the reflector rotational axis;

FIG. 7b schematically shows a front view of the assembly from FIG. 7a;

FIG. 7c schematically shows a top view of the assembly from FIG. 7a;

FIG. 8a schematically shows a partial view of a solar array having a solar module and a reflector element in the side view, with a series connection of the cells of the solar module only in the horizontal direction;

FIG. 8b schematically shows a front view of the assembly from FIG. 8a;

FIG. 9 shows a side view of a solar power plant according to the invention with solar modules and reflector elements arranged in alternation;

FIG. 10 shows a top view of the solar power plant from FIG. 9;

FIG. 11 shows a front view of the solar power plant from . FIG. 9;

FIG. 12 shows a perspective view of the solar power plant from FIG. 9;

FIG. 13 shows an example of the energy yield of a configuration according to the invention, composed of a multipart reflector element and a solar module situated at a distance from the reflector element; and

FIG. 14 shows the possible energy yield of the solar array according to the invention in comparison to conventional arrays.

### DETAILED DESCRIPTION

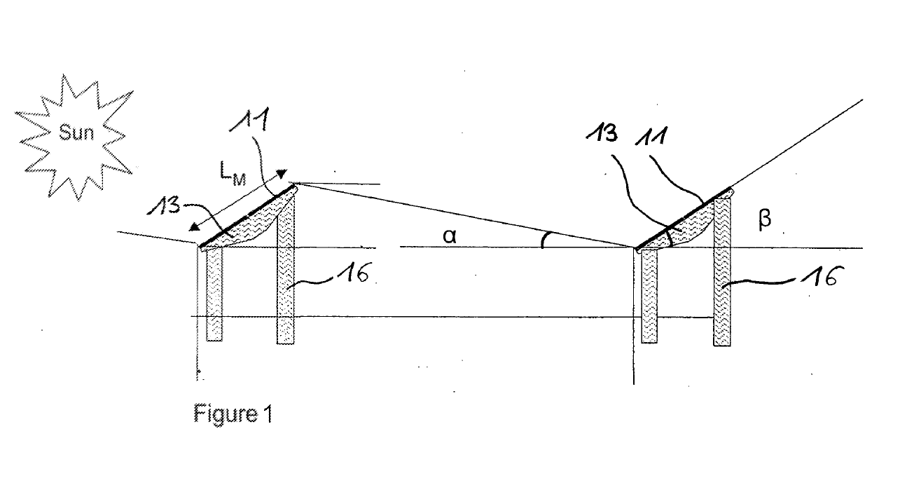

FIG. 1 schematically shows a known configuration of a solar array having a plurality of solar modules 11 situated at a fixed distance from one another. The solar modules 11 are provided on holders 13 which in turn are mounted on poles 16. The solar modules 11 must be set up at a distance from one another which avoids shading of an adjacent solar module to the greatest extent possible at low solar altitude. In the Northern Hemisphere the receiver surfaces of the solar modules are usually oriented to the south in order to obtain the greatest possible energy yield.

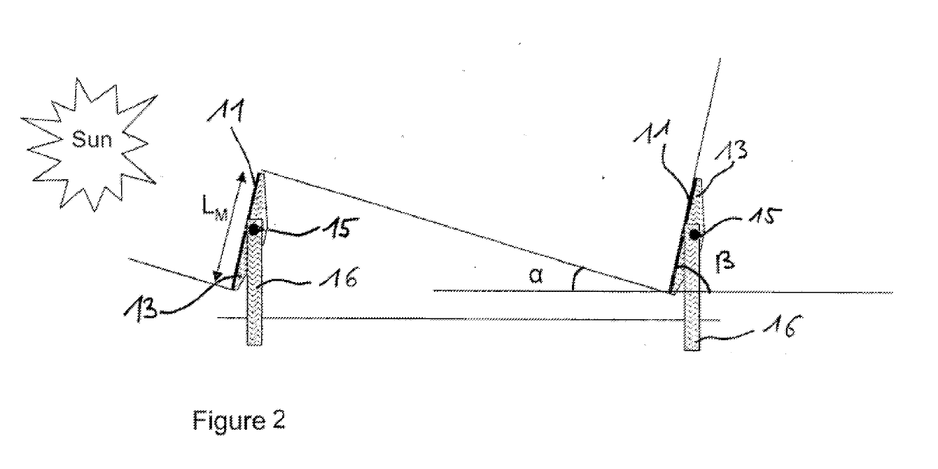

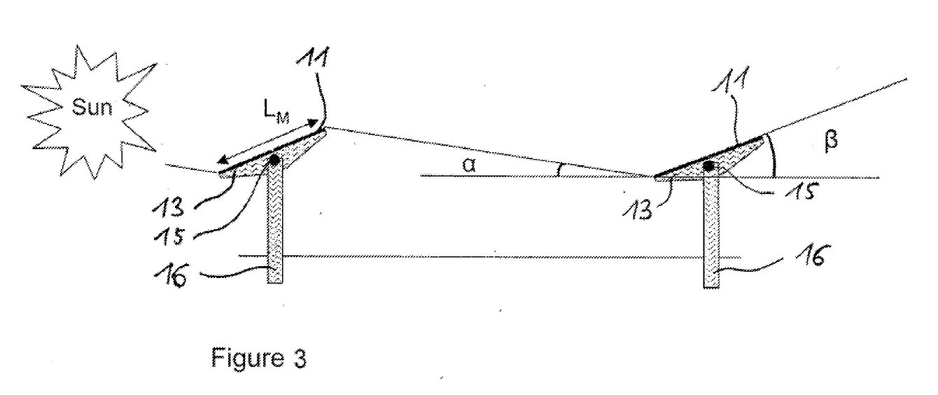

The known solar array according to FIG. 2 differs from that of FIG. 1 in that the solar modules 11 situated on poles 16 may be swiveled about an axis 15. This allows the solar modules to track the course of the solar trajectory. At low solar altitude (flat angle of incidence) the solar modules may be oriented in a relatively flat configuration, thus making it possible to avoid casting shadows on an adjacent solar module (FIG. 3).

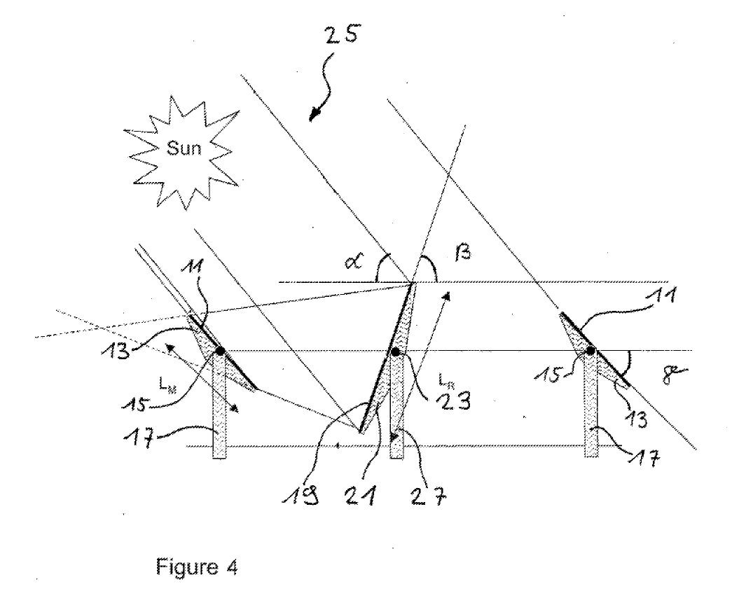

In contrast to the known array according to FIG. 2, the solar array according to the invention as shown in FIG. 4 includes reflector elements 19 in addition to solar modules 11. The reflector elements 19 are each mounted on a holder 21 which is provided on a supporting framework 27 so as to be pivotable about a rotational axis 23. By means of swiveling, the solar radiation 25 striking the reflector element 19 may be projected onto an adjacent solar module 11. The solar modules 11, which are situated at a distance from the reflector elements 19, are mounted on supporting frameworks 17 and may be swiveled about a rotational axis 15. The rotational axes 15 and 23 are aligned in parallel. In the Northern Hemisphere the rotational axes 15, 23 are oriented in the north-south direction. This allows the solar modules 11 and the reflector elements 19 to track the sun, which rises in the east and sets in the west.

In comparison to nonmovable modules, a uniaxial tracking device (not illustrated in the figures) allows much more energy generation. When a uniaxial tracking device is used, in the Northern Hemisphere the solar modules 11 and reflector elements 19 are preferably already configured in a specified inclination in the southerly direction in order to take changing solar trajectories into account over the course of the year.

The reflector element 19 may correspond to a planar mirror surface, or may be designed as a concave mirror surface. In the latter case, projection of sunlight onto the solar module 11 as well as at least uniaxial bundling of the sunlight occur at the same time. The reflector element 19 and the solar module 11 are mounted on a supporting framework 27. The angle of inclination β of the reflector element is adjusted to the solar radiation angle a in such a way that the incident radiation is projected onto the solar module 11. The angle γ of the solar module is selected such that the current generated in the solar module is maximized; i.e., the sum of the energy reflected by the reflector element 19 and the energy absorbed directly from the sun is maximized.

When the rotational axes of the solar modules and reflector elements arranged in a row are oriented in the north-south direction, in the morning the reflector element 19 (see FIG. 4) projects solar radiation onto the facing solar module 11 in the westerly direction, and in the afternoon projects onto the module in the easterly direction (in the Northern Hemisphere).

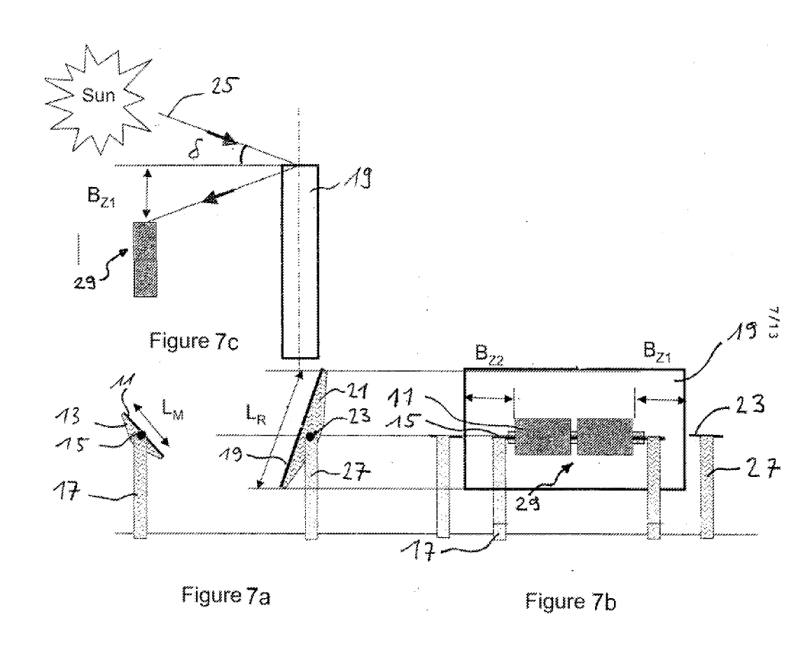

The solar array according to FIGS. 7a, 7b, and 7c is characterized in that the projection surface of the reflector element 19 is maximized to allow the greatest possible amount of radiation energy to be projected onto the solar module 11, thereby generating a higher energy yield in the solar module 11. This may be achieved by selecting the reflector height L_{R} (see FIG. 7a) to be as great as possible. However, the maximum dimensions of the reflector element are limited by the distance from the adjacent solar modules, since it should be possible for the solar modules 11 to undergo further swiveling.

In the horizontal and vertical directions the solar trajectory defines an angle with respect to the rotational axis of the reflector element 19. For optimal projection with changing solar altitude in the vertical direction, the horizontal rotational axis 23 is used (see FIG. 7). A changing angle of incidence a in the horizontal direction (see FIG. 7c) may be compensated for by extending the reflector element by B_{z1}, and B_{z2} on one or both sides in the direction of the rotational axis 23, depending on the geographical location of the array and the direction of the rotational axis 23 (see FIG. 7b), in such a way that the solar radiation 25, which has an angle of incidence δ that is different from 90°, still impinges on the entire solar module 11 with the projected radiation from the reflector (see FIG. 7c).

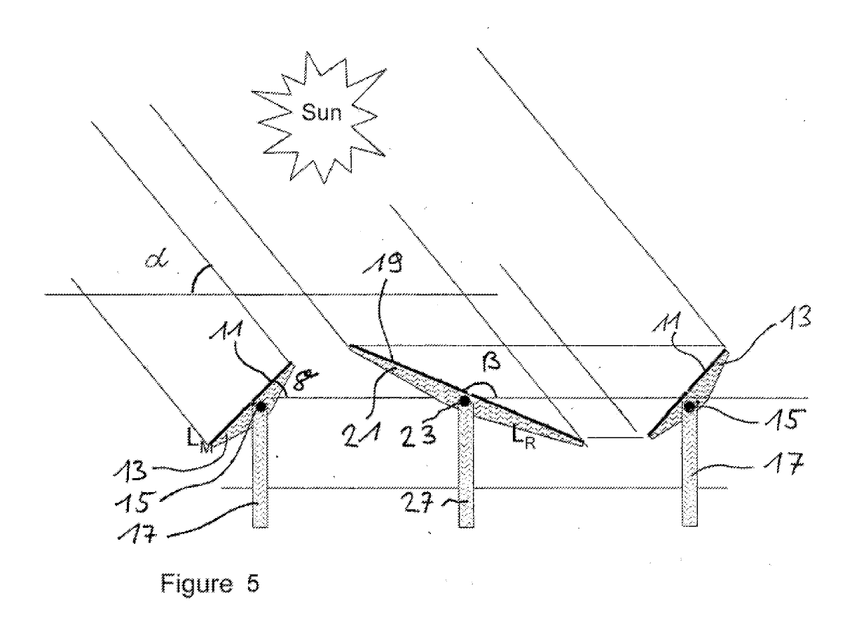

Little or no extension of the reflector elements is necessary when an additional common tracking axis for reflectors and solar modules is present, as illustrated in FIGS. 9-13. In the configuration according to FIG. 5 a reflector element 13 [sic; 19] is provided between two successive rows of solar modules 11. In contrast to the configuration according to FIG. 4, however, the radiation is projected onto the solar module 11 at a relatively flat angle β (maximum 45° with respect to the reflector surface). In FIG. 5 the solar module 11 is mounted so as to be tiltable about the axis 15. A north-south orientation of the rotational axis 15 provides an optimum energy yield when the solar module 11 is tiltable. When the solar module 11 is fixedly mounted a southerly inclination is meaningful, which results in an orientation of the rotational axis 23 of the reflector element 19 in the east-west direction. Orientations in other directions are also possible in principle. In this configuration as well, maximizing the reflector surface according to FIGS. 7a through 7c is meaningful for increasing the energy yield.

In a configuration of the solar modules and reflector elements according to FIGS. 4 through 6 with an orientation of the rotational axis 23 of the reflector element 19 and of the rotational axis 15 of the solar module in the north-south direction, in the morning the reflector element 19 projects the radiation onto the adjacent solar module 11 in the easterly direction (FIG. 4), and in the afternoon projects onto the solar module 19 [sic; 11] in the westerly direction (in the Northern Hemisphere).

For projecting the solar radiation 25 onto the solar modules 11 at various angles of incidence a, a reflector element 19 may be used which not only allows plane-parallel reflection, but also by means of a curved (concave) mirror surface, for example, uniaxially focuses the entire reflected radiation onto the solar module 11 according to FIG. 4. This may be achieved, for example, by using a reflector element 19 composed of multiple smaller planar reflector surfaces which are mounted at different inclinations on the reflector holder 21 in such a way that a concave mirror is formed.

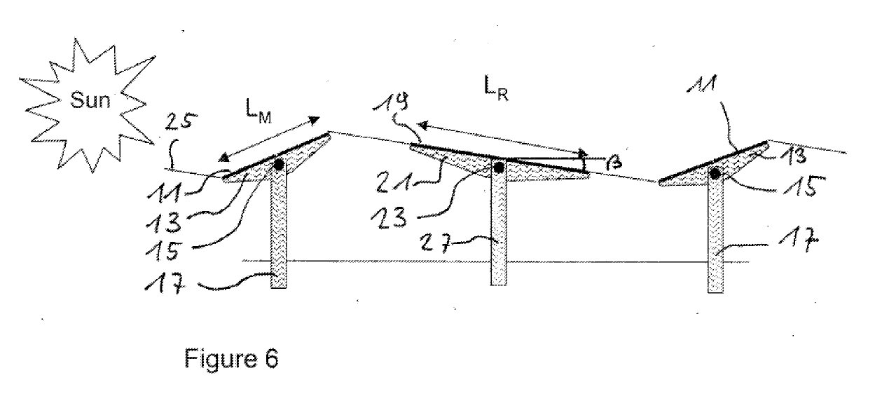

To optimize the energy yield for flat angles of incidence a (see FIG. 6), the reflector element 19 may be positioned at an angle β with respect to the horizontal so that the reflector element does not cast a shadow on an adjacent solar module 11, and also so that optimal conversion of the incident solar energy is ensured in this configuration.

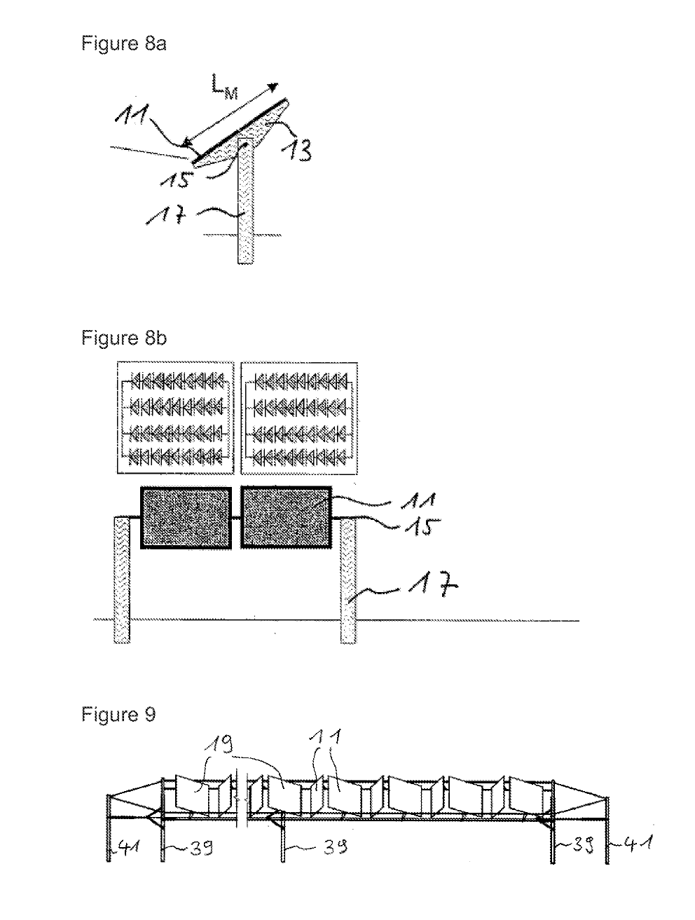

During operation, the solar modules 11 used in a solar array according to the invention are exposed to a higher level of irradiation than is the case for simple solar radiation, since the reflector elements 19 supply additional light. It may therefore be necessary to provide the current conduction on the cell surface itself, and in the supply to the contact plug, for higher currents. As a whole, the solar modules 11 are subjected to a higher radiation, temperature, and current load than in conventional solar arrays. For this reason the photovoltaic module system must be correspondingly designed to meet the increased requirements. In addition, for the solar modules 11 a series connection of cells in the horizontal direction according to FIG. 8b is meaningful to ensure that optimal conversion of energy into electricity occurs when the projection of solar radiation density onto the solar module in the vertical direction is not uniform. This measure reduces the requirements for accuracy of the radiation projection.

During operation of the solar array according to the invention, the reflector element 19 is positioned with respect to the solar module 11, i.e., the solar trajectory is correspondingly tracked, in such a way that the incident solar radiation 25 is substantially projected onto the photovoltaic module surface of an adjacent solar module. The angle of inclination 3 of the reflector element 19 and the angle of inclination y of the solar module 11 are independently adjusted to the particular angle of incidence a so that the resulting current in the solar module 11 which is generated by the direct solar radiation and the radiation reflected by the reflector element 19 are maximized.

To maximize the energy introduced into a reflector element 19, the reflector element should have the largest possible width L_{R} at least transverse to the rotational axis 23 (FIGS. 7a through 7c). For large widths L_{R} the incident radiation is preferably bundled (for example, by means of a concave mirror surface which may also be composed of multiple planar mirrors configured at an angle with respect to one another, or Fresnel elements). The reflector element 19 may also be composed of multiple independent reflector segments. It is also possible to use a flexible reflector element 19 which allows the corresponding radiation projection.

The solar power plant 32 shown in FIGS. 9 through 12 comprises reflector elements 19 and solar, modules 11 provided in alternation. One adjacent reflector element 19 may be associated with each solar module 11. Each reflector element 19 may be composed of a plurality of smaller elements, and the elements may be situated on one or more rotational axes. The solar modules 11 and the reflector elements 19 are pivotably mounted on support cables 33. For this purpose, provided on opposite sides of the solar modules 11 and reflector elements 19 are corresponding articulated joints (not shown in the figures) which articulatedly connect the support cables 33 to the solar modules 11 and reflector elements 19. The support cables 33 are mounted on end-position crossbeams 35 which rest on center supports 39 so as to be pivotable about a rotational axis 37. The support cable 33, designed as a continuous cable, is stretched between poles 41.

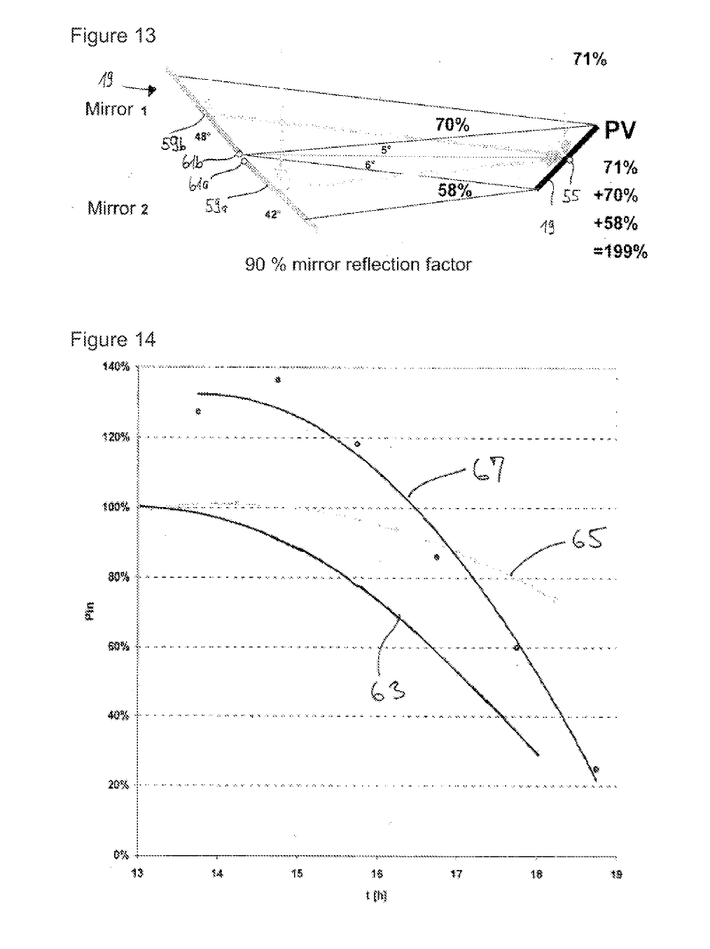

Independent adjusting cables 51, 53 are provided for adjusting the inclination of the solar modules 11 and reflector elements 19. The adjusting cables 51, 53 are suspended from the crossbeams 35 by means of levers 55, 57. The first adjusting cable 51 is connected to the solar modules 11 via coupling elements 59 (first tracking device; FIG. 11). The second adjusting cable 53 is connected to the reflector elements 19 via coupling elements 61 (second tracking device; FIG. 13). The inclinations of the solar modules 11 and reflector elements may thus be independently adjusted by displacing the adjusting cables 51, 53 in the longitudinal direction, using a drive which is not shown in further detail.

Two articulated levers 43, 45 connect each of the crossbeams 35 to the center supports 39 and specify the horizontal inclination of the crossbeams 35. For actuating the articulated levers 43, 45 an actuating cable 47 is provided which is preferably secured to the hinge point 49. The actuating cable 47 may be moved back and forth in the longitudinal direction using drive means not shown in further detail. This causes the articulated levers 43, 45 to be raised up or folded in, thereby adjusting the inclination of the crossbeams 35 (third tracking device; FIGS. 11 and 12). It is obvious to the reader skilled in the art that the inclination of the crossbeams 35 may also be adjusted using hydraulic drives, spindle drives, worm gears, and the like.

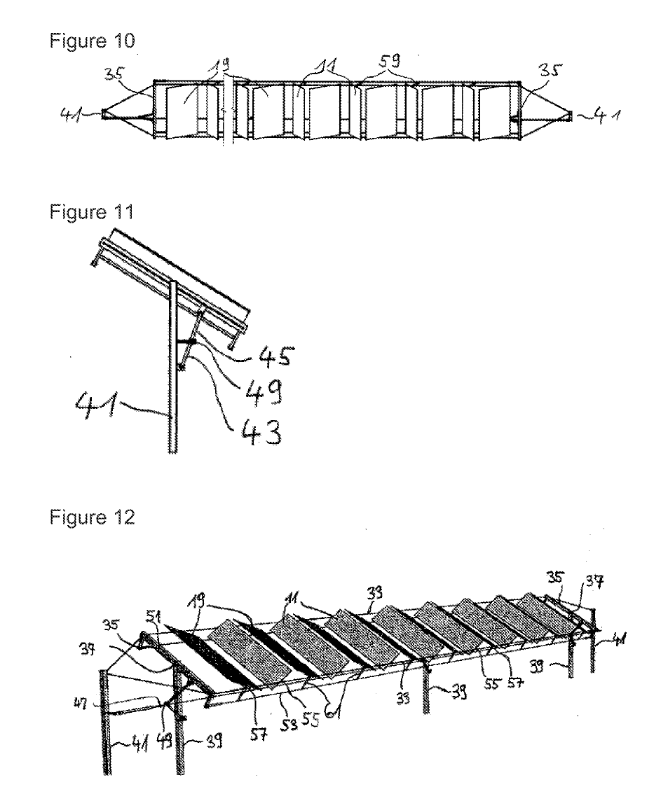

As shown in FIGS. 10 through 13, it is practical for the width (dimension transverse to the swivel axis) of the reflector elements 19 to be greater than that of the solar modules 11. This allows a higher percentage of the incident solar radiation to be projected onto the solar module. The full surface of the solar modules 11 may also be impinged on by reflected radiation when the solar altitude is unfavorable.

Additional center supports 39 and crossbeams 35 may be provided to prevent slack in the support cables and allow absorption of wind forces or snow and ice loads.

The solar array described by way of example may be positioned in the east-west direction in the Northern Hemisphere; i.e., the pole 41 situated on the left side in FIGS. 10, 11, and 13 [sic; 12] is oriented to the east, and the pole on the right side is oriented to the west. In the morning, when the sun is shining from the east, the solar modules 11 are inclined toward the east, and in the afternoon, when the sun is shining from the west, are inclined toward the west. In the morning, for a flat solar altitude the reflector elements 19 are oriented in such a way that they do not cast shadows on the adjacent solar modules 11. For a steeper. solar altitude in the afternoon, the reflector elements 19 may be oriented so that the incident solar radiation is projected onto the respective adjacent solar module 11.

By actuating the articulated levers 43, 45 the inclination may be tracked according to the trajectory of the sun over the course of the year by swiveling the crossbeams about the rotational axis 37 (third tracking device). Thus, the solar modules 11 and reflector elements are each mutually oriented toward the sun in one direction. The first and second tracking devices allow the inclination of the solar modules 11 and reflector elements 19 to be independently oriented about a second and third rotational axis 55, 57, respectively, positioned at right angles to the rotational axis 37. The solar modules 11 are adjusted so that the sum of the direct solar radiation on the solar module 11 and the projected radiation from the reflector element 19 is maximized. However, this configuration may also be provided in the north-south direction or in a slight departure from the ideal east-west or north-south orientation, provided that the required angle of inclination may be correspondingly adjusted. For a north-south orientation of the system, according to the time of day the array is tracked about the rotational axis 37, and the orientation of the reflector elements 19 about the rotational axis 57 for projection of the radiation onto the solar modules 11 as well as the orientation of the solar modules 11 about the rotational axis 55 are each adjusted according to the time of year in such a way that the energy yield on the solar module surface is maximized.

FIG. 13 schematically shows a solar module 11, and a reflector element 19 situated at a distance therefrom. The reflector element 19 is composed of the individual reflector surfaces 59a, 59b, which may be swiveled about respective rotational axes 61a, 61b. More sunlight may be reflected onto the adjacent solar module 11 due to the larger reflector surface area compared to the solar module 11 and the bent configuration of the individual reflector surfaces 59a, 59b relative to one another. Under the assumption that the mirror surfaces of the reflector element have a reflection factor of 90%, 58% and 70% of the light from the individual reflector surfaces 59a and 59b, respectively, may be projected onto the solar module. 71% of the sunlight also reaches the solar module via solar radiation. 100% of the direct solar radiation would be absorbed by the solar module if the solar module surface were oriented at right angles to the incident solar radiation. Overall, 128% of the solar radiation reaches the solar module due to reflection. In total, the light yield is 199% instead of 100%, which would be obtained if only one solar module were used.

The graph according to FIG. 14 shows in a first curve the light yield for a solar array having fixedly mounted solar modules. Curve 65 shows the light yield for a solar array whose receiver surfaces may be tracked according to the solar altitude about an axis. Curve 67 shows the light yield for a solar array according to the invention which has solar modules as well as associated reflector elements. It is clearly seen that over a fairly long time period a much greater quantity of energy can be collected than with a conventional solar array. At the intersection point of curves 65, 67 the reflector elements are adjusted so that no shadows are cast, and the solar elements are optimally oriented to the solar radiation so that the energy yield corresponds to that from the conventional array. Thus, over a long time period over a day the solar array according to the invention has a greater energy yield, and during the remaining time has the energy yield of a conventional array which operates using only solar modules.

1. A solar array comprising:
a plurality of interspaced photovoltaic solar modules,
a plurality of reflector elements at a distance from the solar modules, and
a first tracking device for tracking the solar modules about a first rotational axis, and
a second tracking device independent from the first tracking device for tracking the plurality of reflector elements about a second rotational axis corresponding to a solar trajectory, so that solar radiation striking the reflector elements may be at least partially projected onto the a receiver surface of an adjacent solar module.

2. The solar array according to claim 1, wherein the first and second rotational axes are approximately parallel to one another.

3. The solar array according to claim 1 or 2, further comprising a third tracking device to allow mutual swiveling of the plurality of solar modules and of the plurality of reflector elements about a further respective axis.

4. The solar array according to one of claims 1 through 3, wherein the plurality of solar modules and the plurality of reflector elements are situated on a common supporting framework.

5. The solar array according to one of claims 1 through 4, wherein the solar modules and the reflector elements are respectively mechanically coupled to one another to allow their inclination to be adjusted.

6. The solar array according to one of claims 1 through 5, further comprising at least one row of solar modules situated proximate to one another, and at least one row of reflector elements situated proximate to one another, the row of reflector elements being situated at a distance from the row of solar modules.

7. The solar array according to claim 1 or 2, wherein the plurality of reflector elements allow bundling of the incident solar radiation.

8. The solar array according to one of claims 1 through 7, wherein the plurality of reflector elements have a planar reflector surface.

9. The solar array according to one of claims 1 through 7, wherein the plurality of reflector elements have a concave reflector surface for bundling the radiation.

10. The solar r array according to claim 9, wherein the concave reflector surface is composed of a plurality of individual reflector surfaces having a planar surface.

11. The solar array according to claim 10, wherein the individual reflector surfaces are individually adjustable.

12. The solar array according to one of claims 1 through 11, wherein each solar module is associated with a reflector element, or conversely, a reflector module is associated with a solar module.

13. The solar array according to one of claims 1 through 12, wherein the surface area of a reflector element is larger than the surface area of an adjacent solar module irradiated by the reflector element.

14. The solar array according to one of claims 1 through 13, wherein the plurality of reflector elements are dimensioned and alignable in such a way that when the sunlight has a flat angle of incidence the casting of shadows on adjacent solar modules is largely avoided.

15. The solar array according to one of claims 1 through 14, wherein individual solar cells of the plurality of solar modules are connected in series, parallel to the rotational axis, and are connected in parallel at right angles to the rotational axis.

16. The solar array according to one of claims 1 through 15, wherein the plurality of solar modules are comprised of a plurality of interconnected solar cells, and the solar cells allow a current conduction of more than about 40 mA/cm² 60 mA/cm².

17. The solar array according to one of claims 1 through 16, wherein the plurality of solar modules have has an additional device for dissipation of thermal load.

18. The solar array according to one of claims 1 through 17, wherein the plurality of reflector elements have a reflector surface that absorbs infrared radiation.

19. A method for generating power by use of a solar array, comprising:
providing a plurality of interspaced solar modules configured to be swiveled about at least one rotational axis;
providing a plurality of reflector elements spaced a distance from the plurality of interspaced solar modules and configured to be swiveled about a at least one other rotational axis; and
tracking the solar trajectory in such a way that incident sunlight is projected onto an adjacent solar module.

20. The method according to claim 19, further comprising positioning the plurality of solar modules and plurality of reflector elements one behind the other in alternation on a common supporting framework.

21. The method according to claim 19 or 20, further comprising orienting the plurality of reflector elements at low solar altitude in such a way that shading of an adjacent solar module is avoided.

22. Method according to one of claims 19 through 21, further comprising tracking the plurality of solar modules and plurality of reflector elements according to a solar altitude about a further axis which is substantially perpendicular to the rotational axes.

23. The method according to one of claims 19 through 22, further comprising adjusting the orientation of at least one of the reflector elements and the plurality of the solar modules is so that a resulting wind load is reduced.

24. The method according to one of claims 19 through 22, further comprising adjusting the orientation of at least one of the plurality of reflector elements and the plurality of solar modules so that a resulting snow load is reduced, and sliding off of the snow is facilitated.
